(19) United States
(12) Patent Application Publication
(10) Pub. No.: US 2025/0219594 A1
(43) Pub. Date: Jul. 3, 2025

(54) AMPLIFIER CIRCUIT

(71) Applicant: SMARTER MICROELECTRONICS (SHANGHAI) CO., LTD., Shanghai (CN)

(72) Inventors: Pu TAO, Shanghai (CN); Zhenfei PENG, Shanghai (CN)

(73) Assignee: SMARTER MICROELECTRONICS (SHANGHAI) CO., LTD., Shanghai (CN)

(21) Appl. No.: 19/017,604

(22) Filed: Jan. 11, 2025

(30) Foreign Application Priority Data
Dec. 29, 2023 (CN) 202311872403.0

(51) Int. Cl. H03F 1/52; H03F 3/24

(52) U.S. Cl. CPC H03F 1/52; H03F 3/245; H03F 2200/426; H03F 2200/451

(57) ABSTRACT

The embodiment of the present disclosure provides an amplifier circuit applied to a power amplifier. The amplifier circuit includes a voltage regulating circuit connected with an input terminal of the power amplifier, for sampling an input signal and generating a clamping voltage based on the sampled signal. The voltage regulating circuit is also connected with a bias circuit in the power amplifier, and the clamping voltage is used to limit a bias current of the power amplifier.

### CROSS-REFERENCE TO RELATED APPLICATION

The present application claims priority to Chinese Patent Application No. 202311872403.0 filed on Dec. 29, 2023, the disclosure of which is hereby incorporated by reference in its entirety.

### BACKGROUND

Radio frequency power amplifier (PA) is an indispensable part in the modern communication system, which is used to amplify power of an input signal. However, under some extreme conditions (e.g. low temperature, high mismatch, etc.), a current in the RF power amplifier may exceed a current threshold thereof, which burns out the RF power amplifier. Therefore, a protection circuit is urgently needed when using RF power amplifier to ensure a stable operation of the RF power amplifier.

### SUMMARY

The present disclosure relates to the technical field of semiconductor manufacturing, and particularly to an amplifier circuit.

In view of this, the present disclosure provides an amplifier circuit to solve at least one technical problem in some implementations. In order to achieve the above object, the technical solution of the present disclosure includes as follows. The embodiment of the present disclosure provides an amplifier circuit applied to a power amplifier. The amplifier circuit includes a voltage regulating circuit. The voltage regulating circuit is connected with an input terminal of the power amplifier, for sampling an input signal and generating a clamping voltage based on the sampled signal, and the voltage regulating circuit is also connected with a bias circuit in the power amplifier, and the clamping voltage is used to limit a bias current of the power amplifier.

In some embodiments, the voltage regulating circuit includes a current regulating unit and a reference current unit. The current regulating unit is configured to generate a first current based on the sampled signal, and the reference current unit is configured to generate a second current. An output terminal of the reference current unit is connected with an output terminal of the current regulating unit and connected with an output terminal of the voltage regulating circuit. The first current is automatically regulated based on the second current to change the clamping voltage at an output terminal of the voltage regulating circuit.

In some embodiments, the current regulating unit includes a sampling circuit. The sampling circuit is connected with an input terminal of the power amplifier, for acquiring the sampled signal. The sampling circuit includes a sampling current mirror circuit and a first current mirror circuit. An input terminal of the sampling current mirror circuit is connected with a sampling current source, and the sampling current mirror circuit generates a third current based on the sampling current source and the sampled signal. The first current mirror circuit is coupled to an output terminal of the sampling circuit, for generating the first current based on the third current.

In some embodiments, the clamping voltage at the output terminal of the voltage regulating circuit is raised when the first current is greater than the second current; and the clamping voltage at the output terminal of the voltage regulating circuit is decreased when the second current is less than the first current.

In some embodiments, the first current mirror circuit regulates the first current by regulating and changing an operating state of a transistor in the first current mirror circuit.

In some embodiments, the reference current unit further includes a second current mirror circuit. A first input terminal of the second current mirror circuit is connected with a reference current source, a first output terminal of the second current mirror circuit is connected with an output terminal of the first current mirror circuit, and the second current mirror circuit generates the second current based on a reference current of the reference current source.

In some embodiments, when the first current is less than the second current, the second current mirror circuit regulates the second current by regulating and changing an operating state of a transistor in the second current mirror circuit.

In some embodiments, the reference current unit further includes a third current mirror circuit. An input terminal of the third current mirror circuit is connected with a second output terminal of the second current mirror circuit, an output terminal of the third current mirror circuit is connected with a second input terminal of the second current mirror circuit, and the third current mirror circuit regulates the second current by regulating and changing an operating state of a transistor in the third current mirror circuit.

In some embodiments, the first current mirror circuit further includes a filter circuit between a first transistor and a second transistor within the first current mirror circuit; and/or, the sampling circuit further comprises a sampling filter circuit.

In some embodiments, the voltage regulating circuit is further configured to output multiple clamping voltages, at least part of the clamping voltages are different; and/or, the clamping voltage outputted by the voltage regulating circuit is regulable.

In some embodiments, the amplifier circuit further includes: a switch circuit connected with the output terminal of the voltage regulating circuit, for changing the operating state of the switch circuit according to the clamping voltage, and the switch circuit is further connected with the bias circuit of the power amplifier, for shunting the bias current when the switch circuit is turned on, to limit the bias current of the power amplifier.

In some embodiments, the power amplifier is a multi-stage amplifier, and the bias circuit of at least one-stage amplifier in the multiple-stage amplifier is connected with the switch circuit.

In some embodiments, the bias circuit is configured to provide the bias current to the power amplifier, and the input terminal of the power amplifier is configured to acquire the input signal.

The embodiment of the present disclosure provides an amplifier circuit applied to a power amplifier. The amplifier circuit includes a voltage regulating circuit connected with an input terminal of the power amplifier, for sampling an input signal and generating a clamping voltage based on the sampled signal. The voltage regulating circuit is also connected with a bias circuit in the power amplifier, and the clamping voltage is used to limit the bias current of the power amplifier. In the embodiment of the present disclosure, the power amplifier includes a bias circuit, one end of the voltage regulating circuit is connected with the input end of the power amplifier, and the other end is connected with the bias circuit. The voltage regulating circuit generates a clamping voltage according to the acquired input signal, and limits the bias current provided by the bias circuit to the power amplifier by the clamping voltage, to limit the working current of the power amplifier, thereby ensuring that the power amplifier can operate stably, and avoiding the power amplifier from being burned due to excessive current under extreme conditions, and further reducing the chip burning risk and the equipment repair rate of the power amplifier.

### BRIEF DESCRIPTION OF THE DRAWINGS

FIG. 1 is a schematic structural diagram of a power amplifier and an amplifier circuit according to an embodiment of the present disclosure;

FIG. 2 is a circuit block diagram of a power amplifier and an amplifier circuit according to an embodiment of the present disclosure;

FIG. 3 is a schematic structural diagram of a power amplifier and an amplifier circuit according to another embodiment of the present disclosure;

FIG. 4 is a schematic structural diagram of a circuit in which a power amplifier is a three-stage amplifier provided by an embodiment of the present disclosure;

FIG. 5 is a schematic diagram of a variation curve of a clamping voltage outputted by a voltage regulating circuit with an input power according to an embodiment of the present disclosure;

FIG. 6 is a schematic diagram of a variation curve of a bias current of a power amplifier with an input power when a voltage regulating circuit is provided in an amplifier circuit and when a voltage regulating circuit is not provided according to an embodiment of the present disclosure.

In the drawings: 101—power amplifier; 102—voltage regulating circuit; 103—bias circuit; 104—switch circuit; 201—sampling circuit; 202—sampling current source; 203—first current mirror circuit; 204—second current mirror circuit; 205—reference current source; 206—third current mirror circuit.

### DETAILED DESCRIPTION

Hereinafter, the technical solutions in the embodiments of the present disclosure are clearly and completely described with reference to that embodiment of the present disclosure and the accompanying drawings. It is apparent that the described embodiments are only a part of the embodiments of the present disclosure, rather than all the embodiments. Based on the embodiments in the present disclosure, all other embodiments obtained by those skilled in the art without creative work fall within the scope of protection of the present disclosure.

In the following description, numerous specific details are given in order to provide more thorough understanding of the present disclosure. However, it will be apparent to those skilled in the art that the present disclosure may be practiced without one or more of these details. In other examples, in order to avoid confusion with the present disclosure, some technical features well known in the art are not described, that is, all features of the actual embodiments will not be described herein, and well-known functions and structures will not be described in detail.

In the drawings, dimensions of layers, regions, elements, and relative dimensions thereof may be exaggerated for clarity. The identical reference numerals denote the same element throughout the description.

It should be understood that when an element or layer is described to be “on”, “adjacent to”, “connected with”, or “coupled to” other elements or layers, the element or layer may be directly on, adjacent to, connected with, or coupled to other elements or layers, or there may be an intervening element or layer between the element or layer. Conversely, when an element is described to be “directly on”, “directly adjacent to”, “directly connected with”, or “directly coupled to” other elements or layers, there is no intervening element or layer. It should be understood that although the terms first, second, third, etc. may be used to describe various elements, components, regions, layers, and/or portions, these elements, components, regions, layers, and/or portions should not be limited by these terms. These terms are merely used to distinguish one element, component, region, layer, or portion from another element, component, region, layer, or portion. Accordingly, a first element, component, region, layer, or portion discussed below may be represented as a second element, component, region, layer, or portion without departing from the teachings of the present disclosure. While a second element, component, region, layer, or portion is discussed, it does not imply that a first element, component, region, layer, or portion is necessarily present in the present disclosure.

Spatial relational terms such as “under . . . ”, “below . . . ”, “lower . . . ”, “beneath . . . ”, “above . . . ”, “upper . . . ” and the like may be used herein to describe a relation of one element or feature shown in the drawings in relation to other elements or features for convenience of description. It should be understood that in addition to the orientations shown in the drawings, the spatially relational terms are intended to include different orientations of the devices in use and operation. For example, if a device in the drawings is inverted, then an element or feature described as “under”, or “below”, or “lower” other elements is oriented as “on” other elements or features. Accordingly, the exemplary terms “under” and “below” may include both upper and lower orientations. The devices may additionally be oriented (rotated 90 degrees or other orientations) and the spatial descriptors used herein are interpreted accordingly.

The terms used herein are for the purpose of describing specific embodiments only and are not intended to be a limitation of the present disclosure. As used herein, the singular forms “a”, “an”, and “the” are also intended to include the plural forms unless the context clearly indicates otherwise. It should also be understood that the terms “consist of” and/or “include”, when used in this specification, determine the presence of the features, integers, steps, operations, elements, and/or components, but do not preclude the presence or addition of one or more other features, integers, steps, operations, elements, components, and/or groups. As used herein, the term “and/or” includes any and all combinations of the relevant listed items.

In order to thoroughly understand the present disclosure, detailed steps and detailed structures will be proposed in the following description in order to explain the technical solutions of the present disclosure. Preferred embodiments of the present disclosure are described in detail below, but the present disclosure may have other embodiments in addition to these detailed descriptions.

In the mobile terminal, a radio frequency power amplifier is used to amplify the power of the radio frequency signal to be transmitted, and then the amplified radio frequency signal is fed back to the antenna for outward transmission. In recent years, with the development of communication and consumer electronics, the requirements for the supply voltage, output power and peak-to-average ratio of RF power amplifiers are constantly increasing, all of which put forward higher requirements for the robustness of RF power transmitters. However, under some extreme conditions (e.g. low temperature, high mismatch, etc.), the current in the RF power amplifier can exceed the threshold current thereof, causing the RF power amplifier to burn out. Therefore, how to avoid the burning of power amplifiers in practical applications is an urgent challenge.

Based on this, the embodiments of the present disclosure provide an amplifier circuit capable of effectively limiting the bias signal of the power amplifier to ensure that the power amplifier can operate stably even under a high-power input signal. The amplifier circuit is applied to a power amplifier, and the amplifier circuit includes a voltage regulating circuit connected with an input terminal of the power amplifier. The voltage regulating circuit is configured to sample an input signal and generate a clamping voltage based on the sampled signal. The voltage regulating circuit is also connected with a bias circuit in the power amplifier, and the clamping voltage is used to limit a bias current of the power amplifier. Among them, the clamping voltage not only can directly regulate the voltage of the bias circuit to regulate the current of the bias circuit, but also can regulate the current of the bias circuit by other means such as shunt, which is not limited here. In some embodiments, the voltage regulating circuit is used to automatically regulate the output voltage according to the sampled signal, thereby simplifying the circuit design without complex control structures.

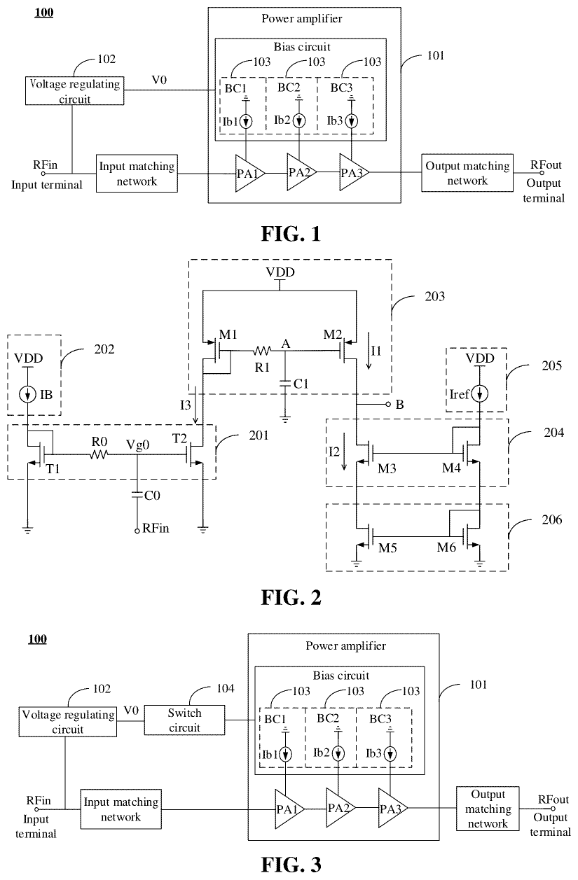

In some embodiments, referring to FIG. 1, FIG. 1 is a schematic structural diagram of a power amplifier and an amplifier circuit according to an embodiment of the present disclosure. An input terminal of the power amplifier 101 is used to acquire an input signal RFin, and an output terminal of the power amplifier 101 is used to transmit an output signal RFout. The amplifier circuit may include a voltage regulating circuit 102 connected with the input terminal of the power amplifier 101, the voltage regulating circuit 102 is connected in parallel to the input terminal of the power amplifier herein, and is configured for sampling the input signal RFin, detecting the magnitude of the input power based on the sampled signal, and determining whether the input power exceeds the magnitude of the preset threshold power, and generating the clamping voltage V0 according to the determination result. The power amplifier 101 also includes a bias circuit 103 which is configured for providing the bias current Ib to the power amplifier 101, and the voltage regulating circuit 102 is also connected with the bias circuit 103 of the power amplifier for sending the clamping voltage V0 to the bias circuit 103 to limit the bias current Ib of the power amplifier, and limit an operation current of the power amplifier, so as to ensure that the power amplifier can operate stably, thereby avoiding the power amplifier being burned due to excessive power under extreme conditions, and reducing the burning risk, and the equipment repair rate of the power amplifier.

In some embodiments, the power amplifier 101 may be a single-stage amplifier or a multi-stage amplifier, and each-stage amplifier includes a radio frequency power amplifier PA, in other words, the power amplifier includes N cascaded radio frequency power amplifiers, and N is greater than or equal to 1. When the power amplifier 101 is a single-stage amplifier, the bias circuit provided in the single-stage amplifier is connected with the voltage regulating circuit. When the power amplifier 101 is a multi-stage amplifier, a bias circuit of at least one-stage amplifier in the multi-stage amplifier is connected with a voltage regulating circuit.

The power amplifier shown in FIG. 1 is a three-stage amplifier (such as a first amplifier PA1, a second amplifier PA2, and a third amplifier PA3), and the power amplifier includes three bias circuits 103 (such as a first bias circuit BC1, a second bias circuit BC2, and a third bias circuit BC3), which respectively provide bias currents to amplifiers, for example, the first bias circuit BC1 supplies a first bias current Ib1 to the first amplifier PA1, the second bias circuit BC2 supplies a second bias current Ib2 to the second amplifier PA2, and the third bias circuit BC3 supplies a third bias current Ib3 to the third amplifier PA3. The voltage regulating circuit 102 may be connected only with any one of the three bias circuits 103, or may be connected with all of the three bias circuits 103, or may be connected in another connection mode. In other words, the clamping voltage V0 generated by the voltage regulating circuit 102 may be transmitted only to any one of the three bias circuits 103 to limit the input power of one power amplifier, may be transmitted to the three bias circuits 103 respectively to limit the input power of each of the three power amplifiers, or may be transmitted in other transmission modes to limit the input power, which is not repeatedly here anymore.

In some embodiments, the voltage regulating circuit is further configured to output different clamping voltages, i.e., the output voltage of the voltage regulating circuit is regulable to limit the current of the amplifier at different frequency bands.

In some embodiments, the voltage regulating circuit has a plurality of output terminals for connection with the amplifier, and the regulable voltages outputted by the plurality of output terminals may be the same, partially the same, or different from each other, which is not limited here.

In some embodiments, the voltage regulating circuitry may also be selectively coupled to the bias circuitry in the multi-stage amplifier to limit the selected amplifier.

In some embodiments, the amplifier circuit further includes an input matching network (IMN) and an output matching network (OMN). The input matching network is provided between an external load (here is the input terminal) and the power amplifier for matching an impedance of the input signal RFin with an input impedance of the power amplifier to transmit the energy of the input signal to the greatest extent, thereby ensuring that the input signal can effectively be inputted to the power amplifier and reducing reflection and loss of the input signal. The output matching network is provided between the power amplifier and the external load (here is the output terminal), and is configured to match the impedance of the output signal RFout of the power amplifier with the external load, thereby reducing the reflection and loss of the output signal, and regulating the performance of the power amplifier. In the embodiment of the present disclosure, the voltage regulating circuit may be provided between the input terminal and the input matching network (as shown in FIG. 1), or may be provided between the input matching network and the source terminal of the power amplifier.

In some embodiments, the voltage regulating circuit includes: a current regulating unit configured to generate a first current based on the sampled signal; a reference current unit configured to generate a second current, an output terminal of the reference current unit being connected with an output terminal of the current regulating unit and connected with an output terminal of the voltage regulating circuit. The first current is automatically regulated based on the second current to change the clamping voltage at an output terminal of the voltage regulating circuit.

In some embodiments, the current regulating unit includes a sampling circuit. An input terminal of the sampling circuit is connected with an input terminal of the power amplifier, and sampling circuit is configured to sample the input signal Rfin to obtain a sampled signal, and the sampled signal is an input signal Rfin at a preset proportion.

In some embodiments, the sampling circuit includes a transistor, and the transistor may be a first Metal-Oxide-Semiconductor (MOS) transistor. The gate of the first MOS transistor is used to acquire the sampled signal, and superimpose the sampled signal with a bias signal of the first MOS transistor to cause the first MOS transistor to generate a first current based on the sampled signal.

In some embodiments, the sampling circuit includes a sampling current mirror circuit which includes a first MOS transistor and a second MOS transistor, and the sampled signal is superimposed with a gate signal of the first MOS transistor to cause the first MOS transistor in the current mirror circuit to output a first current.

In some embodiments, the sampling circuit includes a sampling current mirror circuit. An input terminal of the sampling current mirror circuit is connected with a sampling current source, and the sampling current mirror circuit generates a first current based on the sampling current source and the sampled signal. Specifically, the current mirror circuit replicates a current of the sampled current source and superimposes the current with the sampled signal to generate the first current.

In some embodiments, the sampling circuit includes a sampling current mirror circuit and a first current mirror circuit. The sampling current mirror circuit is configured to acquire a sampled signal and generate a third current based on the sampled signal, an output terminal of the sampling current mirror circuit is connected with the first current mirror circuit, and the first current mirror circuit generates a first current based on the third current.

In some embodiments, exemplarily, as shown in FIG. 2, the sampling current mirror circuit includes a first MOS transistor T1 and a second MOS transistor T2, a drain of the first MOS transistor T1 is connected with the output terminal of the sampling current source 202, a source of the first MOS transistor T1 is grounded, a gate of the first MOS transistor T1 is also connected with the drain of the first MOS transistor T1, the gate of the first MOS transistor T1 is connected with a gate of the second MOS transistor T2, a source of the second MOS transistor T2 is grounded and a drain of the second MOS transistor T2 is connected with the first current mirror circuit 203. The sampling current source 202 is configured to provide a sampling current IB to the sampling circuit 201, and the sampling current mirror circuit generates a third current I3 based on the sampling current IB and the sampled signal. Specifically, the first MOS transistor T1 supplies the sampling current to the second MOS transistor T2 to generate a gate bias voltage at the gate of the second MOS transistor T2, and the gate bias voltage is superimposed with the radio frequency voltage corresponding to the sampled signal to form a turn-on voltage Vg0, and the turn-on voltage Vg0 causes the second MOS transistor T2 to be turned on to generate a third current I3 (i.e., the drain current of the second MOS transistor).

The first current mirror circuit 203 is coupled to the output terminal of the sampling circuit 201, and is configured for generating a first current I1 based on the third current I3. Specifically, referring to FIG. 2, the first current mirror circuit 203 includes a first transistor M1 and a second transistor M2, the source of the first transistor M1 is coupled to the source of the second transistor M2, the gate of the first transistor M1 is coupled to the gate of the second transistor M2, the drain of the first transistor M1 is coupled to the drain of the second MOS transistor T2, the drain of the first transistor M1 is also coupled to the gate of the first transistor M1, and the drain of the second transistor M2 is connected with the output terminal of the reference current unit. It should be noted that the first current mirror circuit 203 may mirror the third current I3 to form the first current I1, and the third current I3 is the same as the first current I1 here. As shown in FIG. 2, the first current I1 is transmitted to the output terminal B of the voltage regulating circuit through the output terminal of the current regulating unit.

In some embodiments, the sampling circuit further includes a sampling filter circuit including a first capacitor and a first resistor. Exemplarily, as shown in FIG. 2, the first electrode of the first capacitor C0 is connected with the input terminal of the power amplifier, and the second electrode of the first capacitor C0 is connected with the gate of the second MOS transistor T2; the first resistor R0 is connected in series between the first MOS transistor and the second MOS transistor, and is connected with the second electrode of the first capacitor.

In some embodiments, the first current mirror circuit further includes a filter circuit between two transistors of the filter circuit. Exemplarily, as shown in FIG. 2, the first current mirror circuit 203 further includes a filter circuit between the first transistor M1 and the second transistor M2, the filter circuit includes a second resistor R1 and a second capacitor C1, the second resistor R1 is connected in series between the gate of the first transistor M1 and the gate of the second transistor M2, a common terminal A between the second resistor R1 and the gate of the second transistor M2 is also connected with the first electrode of the second capacitor C1, and the second electrode of the second capacitor C1 is grounded.

In some embodiments, the first current mirror circuit includes a plurality of second transistors, and the plurality of second transistors and the first transistor may form current mirror circuits at different proportions to output different clamping voltages V0. At this time, the bias circuit may be selectively connected with one of the second transistors.

In some embodiments, the bias circuit may also be selectively connected with the plurality of second transistors to provide different clamping voltages V0 to the bias circuit.

In some embodiments, the plurality of second transistors may also at least partially together with the first transistor to constitute a current mirror circuit at the same proportion.

It should be noted that when the sizes of the first transistor M1 and the second transistor M2 and the sampling current supplied by the sampling current source are fixed, the magnitude of the first current I1 is directly proportional to the magnitude of the input signal, that is, the larger the input signal, the larger the first current I1, and the smaller the input signal, the smaller the first current I1. That is, the magnitude of the first current I1 can be used to characterize the magnitude of the input power, that is, the magnitude of the first current I1 is directly proportional to the magnitude of the input power, the greater the first current I1 is, the greater the input power is, and the smaller the first current I1 is, the smaller the input power is.

In some embodiments, the reference current unit includes a current source for providing the second current.

In some embodiments, a current of the current source may be regulated to output different second currents.

In some embodiments, the reference current unit includes a second current mirror circuit and a reference current source, a first input terminal of the second current mirror circuit is connected with the reference current source, a first output terminal of the second current mirror circuit is connected with an output terminal of the first current mirror circuit, and the second current mirror circuit generates a second current based on the reference current of the reference current source.

Exemplarily, referring to FIG. 2, the second current mirror circuit 204 includes a third transistor M3 and a fourth transistor M4, a source of the third transistor M3 is coupled to a source of the fourth transistor M4, a gate of the third transistor M3 is coupled to a gate of the fourth transistor M4, a drain of the third transistor M3 is coupled to the drain of the second transistor M2, a drain of the fourth transistor M4 is coupled to the output terminal of the reference current source 205, and the gate of the fourth transistor M4 is also coupled to the drain of the fourth transistor M4. The reference current source 205 is used to provide a reference current Iref to the second current mirror circuit 204, and the second current mirror circuit 204 generates a second current I2 based on the reference current Iref.

In the operation process, when the first current I1 and the second current I2 change, that is, the first current I1 and the second current I2 are different, the clamping voltage changes based on the first current I1 and the second current I2, to regulate the first current I1 and the second current I2 to enable the first current I2 and the second current I2 to be the same. The clamping voltage V0 at the output terminal of the voltage regulating circuit is raised when the first current I1 is greater than the second current I2. The clamping voltage V0 at the output terminal of the voltage regulating circuit is decreased when the second current I2 is greater than the first current I1.

In some specific embodiments, the first current mirror circuit may regulate and change an operating state of the transistor in the first current mirror circuit, to regulate the first current I1.

Exemplarily, referring to FIG. 2, when the first current I1 is greater than the second current I2, since the first current I1 and the second current I2 are in the same path, the second transistor M2 enters a linear region in order to make the first current I1 and the second current I2 tend to be the same, and the clamping voltage V0 raises to regulate the first current I1 until the first current I1 is the same as the second current I2.

In some specific embodiments, when the second current I2 is greater than the first current I1, the second current mirror circuit may regulate and change the operating state of the transistor in the second current mirror circuit by regulate the second current.

Exemplarily, referring to FIG. 2, when the first current I1 is less than the second current I2, since the first current I1 and the second current I2 are in the same path, the third transistor M3 enters the linear region in order to make the first current I1 and the second current I2 tend to be the same, and the clamping voltage V0 decreases to regulate the second current I2 until the second current I2 is the same as the first current I1.

In some embodiments, the reference current unit further includes a third current mirror circuit 206, an input terminal of the third current mirror circuit 206 is connected with a second output terminal of the second current mirror circuit 204, an output terminal of the third current mirror circuit 206 is connected with a second input terminal of the second current mirror circuit 204, and the third current mirror circuit 206 can regulate and change the operating state of the transistor in the third current mirror circuit to regulate the second current I2.

Exemplarily, referring to FIG. 2, the third current mirror circuit 206 includes a fifth transistor M5 and a sixth transistor M6. A gate of the fifth transistor M5 is coupled to a gate of the sixth transistor M6, a source of the fifth transistor M5 is grounded, a source of the sixth transistor M6 is grounded, a drain of the fifth transistor M5 is connected with the source of the third transistor M3 of the second current mirror circuit, a drain of the sixth transistor M6 is connected with the source of the fourth transistor M4 of the second current mirror circuit. The third current mirror circuit, like the second current mirror circuit, can regulate and change the operating state of the transistor in the current mirror circuit to regulate the second current.

In the amplifier circuit, only the second current mirror circuit 204 may be provided, only the third current mirror circuit 206 may be provided, or both the second current mirror circuit 204 and the third current mirror circuit 206 may be provided. It should be understood that providing both the second current mirror circuit and the third current mirror circuit may make the second current I2 more stable. In addition, when only the third current mirror circuit 206 is provided in the circuit, only the fifth transistor M5 enters the linear region when the first current I1 is less than the second current I2, and the clamping voltage V0 decreases to regulate the second current I2 until the second current I2 is the same as the first current I1.

In some embodiments, referring to FIG. 3, the amplifier circuit further includes: a switch circuit 104 connected with the output terminal of the voltage regulating circuit 102 for changing the operating state of the switch circuit according to the clamping voltage, and the switch circuit 104 is also connected with the bias circuit 103 of the power amplifier for shunting the bias current when the switch circuit 104 is turned on, to limit the bias current of the power amplifier 101, thereby limiting the output power of the power amplifier.

Exemplarily, referring to FIG. 3, the switch circuit 104 is connected in series between the output terminal of the voltage regulating circuit 102 and the bias circuit 103 for changing the on or off of the switch circuit 104 according to the clamping voltage V0. When the switch circuit 104 is turned on, the bias current provided by the bias circuit 103 is shunt, to limit the bias current provided to the power amplifier, and limit the operating current of the power amplifier, thereby ensuring that the power amplifier can operate stably, and avoiding the power amplifier from being burned due to excessive power under extreme conditions, and reducing the chip burning risk of the power amplifier and apparently reducing the equipment repair rate.

In some embodiments, when the power amplifier is a multi-stage amplifier, the bias circuit of at least one-stage amplifier in the multi-stage amplifier is connected with the switch circuit.

Specifically, referring to FIG. 3, when the power amplifier 101 is a single-stage amplifier, the bias circuit provided in the single-stage amplifier is connected with the voltage regulating circuit 102 through the switch circuit 104. When the power amplifier 101 is a multi-stage amplifier, the multi-stage amplifier includes a plurality of bias circuits 103, and at least one bias circuit of the plurality of bias circuits is connected with the voltage regulating circuit 102 through the switch circuit 104. In other words, the switch circuit may limit at least part of the bias current of the amplifier according to the clamping voltage V0 to limit the output power of the amplifier. It should be understood that one or more switches may be provided in the switch circuit for turning on or off.

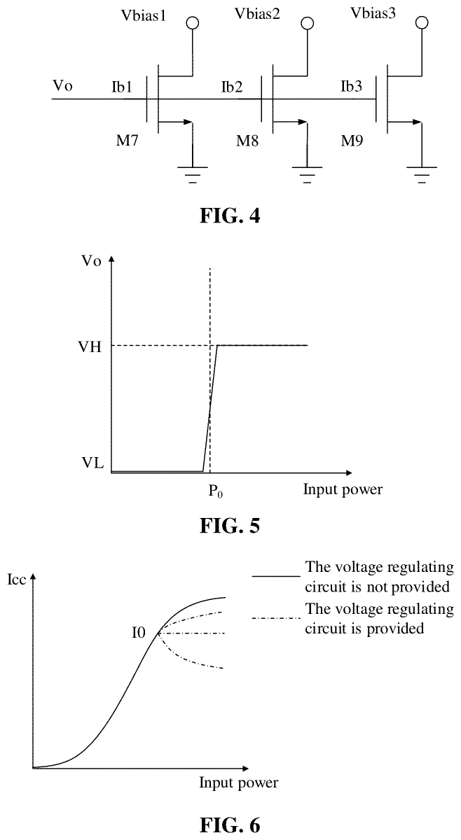

In some embodiments, referring to FIG. 4, the power amplifier is a three-stage amplifier including a seventh transistor M7, an eighth transistor M8 and a ninth transistor M9. The clamping voltage V0 is respectively connected with the gates of the seventh transistor M7, the eighth transistor M8 and the ninth transistor M9, and drains of the seventh transistor M7, the eighth transistor M8 and the ninth transistor M9 are respectively connected with the bias circuit nodes such as the first voltage source Vbias1, the second voltage source Vbias2 and the third voltage source Vbias3 of the three-stage amplifier. When the clamping voltage V0 raises to enable the seventh transistor M7, the eighth transistor M8 and the ninth transistor M9 to be turned on, the seventh transistor M7, the eighth transistor M8 and the ninth transistor M9 draw out the corresponding three bias currents in the three-stage amplifier, that is, the bias currents (e.g., Ib1, Ib2, and Ib3) corresponding to the seventh transistor M7, the eighth transistor M8, and the ninth transistor M9 are reduced. In this way, the gain and output power of the three-stage amplifier are limited, thereby avoiding the damage of the three-stage amplifier due to excessive input power, and realizing the function of over-drive protection.

In some embodiments, the clamping voltage V0 outputted by the regulating circuit may also directly turn off the DAC of the bias circuit, thereby turning the bias circuit off.

It should be noted that the type of transistor in each embodiment of the present disclosure is not limited, and the transistor may be a bipolar junction transistor or a field effect transistor. For convenience of description, only one type is introduced in each embodiment, and it is understood that the transistor in each embodiment may be replaced with another type of transistor, and will not be repeated here.

In other embodiments, when the sizes of the transistors are fixed, a threshold at which the voltage regulating circuit is turned on can be controlled by the current value of the reference current Iref increased by regulating the reference current source, and the accuracy of the threshold is largely determined based on a current accuracy of the reference current Iref. In other words, in the implementation of the present disclosure, providing the voltage regulating circuit in the amplifier circuit can realize reducing or turning off the bias current of the power amplifier when a swing of the output voltage of the power amplifier reaches a certain threshold value, to ensure that neither the output voltage nor the current of the power amplifier can be continuously increased, and the reference current is controlled by the reference current source, to ensure that the amplifier circuit can have higher accuracy and improve the control accuracy of the input power.

FIG. 5 is a schematic diagram of a variation curve of an output voltage (i.e., a clamping voltage V0) of a voltage regulating circuit in an amplifier circuit provided in an embodiment of the present disclosure with an input power. The abscissa denotes the input power, and the ordinate denotes the clamping voltage V0. When the input power is greater than a certain threshold P0, the clamping voltage V0 raises from the low level VL to the high level VH, the raising slope depends on a gain of the voltage regulating circuit.

Referring to FIG. 6, FIG. 6 is a schematic diagram of a variation curve of a bias current Icc of a power amplifier with an input power when a voltage regulating circuit is provided in an amplifier circuit and when a voltage regulating circuit is not provided in an embodiment of the present disclosure, the abscissa is the input power, and the ordinate is the bias current Icc of the power amplifier. As can be seen from FIG. 6, the bias current Icc of the power amplifier also increases with the continuous increase of input power. When a voltage regulating circuit is provided in the amplifier circuit, the bias current Icc of the power amplifier is limited after increasing to a certain threshold current I0. For example, after the bias current increases to a certain threshold current I0, an increasing amount decreases, or the bias current does no longer increases, or gradually decreases. When the voltage regulating circuit is not provided in the amplifier circuit, the bias current Icc of the power amplifier continues increasing after increasing to the threshold current, which will burn the power amplifier. In other words, in case that a voltage regulating circuit is provided in the amplifier circuit, the input power of the power amplifier can be effectively limited and regulated to ensure that the power amplifier can operate stably, thereby preventing the power amplifier from being burned due to excessive current under extreme conditions.

Based on this, the power amplifier in the embodiment of the present disclosure includes a bias circuit, one end of the voltage regulating circuit is connected with the input end of the power amplifier, and the other end is connected with the bias circuit. The voltage regulating circuit generates a clamping voltage according to the acquired input signal, and the clamping voltage is used to limit the bias current raised by the bias circuit to the power amplifier to limit an operating current of the power amplifier, thereby ensuring that the power amplifier can operate stably, avoiding the power amplifier being burned due to excessive power under extreme conditions, and further reducing the chip burning risk of the power amplifier and apparently reducing the equipment repair rate.

Based on the above described amplifier circuit, the embodiment of the present disclosure further provides an amplifier device. The amplifier device includes at least the amplifier circuit described in the above described embodiment of the present disclosure.

The embodiment of the present disclosure further provides an electronic device. The electronic device at least includes an amplifier device as described in the above embodiment of the present disclosure.

It is to be understood that references throughout the specification to “one embodiment” or “an embodiment” mean that a particular feature, structure or characteristic related to the embodiment is included in at least one embodiment of the present disclosure. Thus, the expressions “in one embodiment” or “in an embodiment” appearing throughout the specification do not necessarily refer to the same embodiment. Furthermore, these particular features, structures or characteristics may be incorporated in any suitable manner in one or more embodiments. It should be understood that in various embodiments of the present disclosure, the size of the sequence number of the above described processes does not mean the sequence of execution, and the sequence of execution of each process should be determined by its function and internal logic, and should not constitute any limitation on the implementation process of the embodiments of the present disclosure. The above described serial numbers of the embodiments of the present disclosure are merely for description, and do not represent the advantages and disadvantages of the embodiments.

The foregoing is only a preferred embodiment of the present disclosure, and does not limit the patent scope of the present disclosure accordingly. Any equivalent structural transformation made based on the contents of the present specification and the accompanying drawings under the inventive concept of the present disclosure, or directly/indirectly applied to other related technical fields, is contained in the patent protection scope of the present disclosure.

1. An amplifier circuit applied to a power amplifier, comprising:
a voltage regulating circuit connected with an input terminal of the power amplifier, for sampling an input signal and generating a clamping voltage based on the sampled signal, wherein the voltage regulating circuit is also connected with a bias circuit in the power amplifier, and the clamping voltage is used to limit a bias current of the power amplifier.

2. The amplifier circuit of claim 1, wherein the voltage regulating circuit comprises:
a current regulating unit configured to generate a first current based on the sampled signal;
a reference current unit configured to generate a second current, wherein an output terminal of the reference current unit is connected with an output terminal of the current regulating unit and connected with an output terminal of the voltage regulating circuit; and
the first current is automatically regulated based on the second current to change the clamping voltage at an output terminal of the voltage regulating circuit.

3. The amplifier circuit of claim 2, wherein the current regulating unit comprises:
a sampling circuit connected with an input terminal of the power amplifier, for acquiring the sampled signal, wherein the sampling circuit comprises a sampling current mirror circuit, an input terminal of the sampling current mirror circuit is connected with a sampling current source, and the sampling current mirror circuit is configured to generate a third current based on the sampling current source and the sampled signal; and
a first current mirror circuit coupled to an output terminal of the sampling circuit, for generating the first current based on the third current.

4. The amplifier circuit of claim 2, wherein
when the first current is greater than the second current, the clamping voltage at the output terminal of the voltage regulating circuit is raised; and
when the second current is less than the first current, the clamping voltage at the output terminal of the voltage regulating circuit is decreased.

5. The amplifier circuit of claim 2, wherein the first current mirror circuit is configured to regulate the first current by regulating and changing an operating state of a transistor in the first current mirror circuit.

6. The amplifier circuit of claim 2, wherein the reference current unit comprises:
a second current mirror circuit, wherein a first input terminal of the second current mirror circuit is connected with a reference current source, a first output terminal of the second current mirror circuit is connected with an output terminal of the first current mirror circuit, and
the second current mirror circuit is configured to generate the second current based on a reference current of the reference current source.

7. The amplifier circuit of claim 6, wherein when the first current is less than the second current, the second current mirror circuit is configured to regulate the second current by regulating and changing an operating state of a transistor in the second current mirror circuit.

8. The amplifier circuit of claim 7, wherein the reference current unit further comprises a third current mirror circuit, an input terminal of the third current mirror circuit is connected with a second output terminal of the second current mirror circuit, an output terminal of the third current mirror circuit is connected with a second input terminal of the second current mirror circuit, and
the third current mirror circuit is configured to regulate the second current by regulating and changing an operating state of a transistor in the third current mirror circuit.

9. The amplifier circuit of claim 3, wherein
the first current mirror circuit further comprises a filter circuit between a first transistor and a second transistor within the first current mirror circuit; and/or,
the sampling circuit further comprises a sampling filter circuit.

10. The amplifier circuit of claim 1, wherein the voltage regulating circuit is further configured to output a plurality of clamping voltages, at least part of the plurality of clamping voltages are different; and/or,
the clamping voltage outputted by the voltage regulating circuit is regulable.

11. The amplifier circuit of claim 1, wherein the amplifier circuit further comprises:
a switch circuit connected with the output terminal of the voltage regulating circuit for changing an operating state of the switch circuit according to the clamping voltage, wherein the switch circuit is further connected with the bias circuit of the power amplifier for shunting the bias current when the switch circuit is turned on, to limit the bias current of the power amplifier.

12. The amplifier circuit of claim 11, wherein the power amplifier is a multi-stage amplifier, and the bias circuit of at least one-stage amplifier in the multi-stage amplifier is connected with the switch circuit.

13. The amplifier circuit of claim 1, wherein the bias circuit is configured to provide the bias current to the power amplifier, and the input terminal of the power amplifier is configured to acquire the input signal.
